(19) United States
(12) Patent Application Publication
(10) Pub. No.: US 2024/0250010 A1
(43) Pub. Date: Jul. 25, 2024

(54) SEMICONDUCTOR PACKAGE

(71) Applicant: LG INNOTEK CO., LTD., Seoul (KR)

(72) Inventor: IL SIK NAM, Seoul (KR)

(73) Assignee: LG INNOTEK CO., LTD., Seoul (KR)

(21) Appl. No.: 18/290,422

(22) PCT Filed: May 13, 2022
(86) PCT No.: PCT/KR2022/006891

§ 371 Date: Nov. 13, 2023

(30) Foreign Application Priority Data
May 13, 2021 (KR) 10-2021-0062276

(51) Int. Cl. H01L 23/498; H01L 23/00

(52) U.S. Cl. CPC H01L 23/49838; H01L 24/16; H01L 24/81; H01L 2224/16227; H01L 2224/81385

(57) ABSTRACT

A semiconductor package according to an embodiment includes a first insulating layer; a first pad disposed on an upper surface of the first insulating layer; a second pad disposed on an upper surface of the first insulating layer and spaced apart from the first pad in a horizontal direction; and a second insulating layer disposed on the first pad and including a first opening overlapping an upper surface of the first pad in a vertical direction, wherein an upper surface of the second pad includes a recess, and wherein the recess of the second pad is closer to a lower surface of the first insulating layer than the upper surface of the first pad.

### TECHNICAL FIELD

An embodiment relates to a semiconductor package.

### BACKGROUND ART

Electric/electronic products are progressing high-performance, and thus, technologies for placing more semiconductor devices in limited size semiconductor package substrates are proposed and studied. However, a general semiconductor package is based on a single semiconductor device, so there is a limit to the desired performance.

A typical semiconductor package has a processor package on which a processor chip is attached and a memory package on which a memory chip is attached, connected as one. The semiconductor package manufactures processor chips and memory chips into one integrated package. This has the advantage of reducing a chip mounting area and enabling high-speed signal transmission through a short path. Due to these advantages, the above semiconductor package is widely applied to mobile devices, etc.

Meanwhile, package integration is required recently due to the higher specifications of electronic devices such as mobile devices and the adoption of HBM (High Bandwidth Memory).

At this time, a circuit pattern layer of semiconductor packages is becoming increasingly finer in order to mount multiple chips on one circuit board. At this time, in the conventional semiconductor package, problems such as diffusion of the solder balls occur in a process of arranging the solder balls on the miniaturized pattern. In addition, the diffused solder balls are connected to adjacent patterns, thereby causing reliability problems such as circuit shorts.

### DISCLOSURE

### Technical Problem

The embodiment provides a semiconductor package with a new structure.

In addition, the embodiment provides a semiconductor package that can solve reliability problems caused by the diffusion of connection parts.

The technical problem to be solved in the embodiment is not limited to the technical problem mentioned above, and another technical problem not mentioned will be clearly understood by those of ordinary skill in the art to which the present invention belongs from the following description.

### Technical Solution

A semiconductor package according to an embodiment comprises a first insulating layer; a first pad disposed on an upper surface of the first insulating layer; a second pad disposed on an upper surface of the first insulating layer and spaced apart from the first pad in a horizontal direction; and a second insulating layer disposed on the first pad and including a first opening overlapping an upper surface of the first pad in a vertical direction, wherein an upper surface of the second pad includes a recess, and wherein the recess of the second pad is closer to a lower surface of the first insulating layer than the upper surface of the first pad.

In addition, the second insulating layer is disposed on the upper surface of the first insulating layer.

In addition, the second insulating layer includes a second opening that entirely overlaps the upper surface of the second pad in the vertical direction.

In addition, a height of the upper surface of each of the first pad and the second pad is less than or equal to the height of the upper surface of the first insulating layer.

In addition, the first pad has a first plan view shape, and the second pad has a second plan view shape different from the first plan view shape.

In addition, the upper surface of the second pad includes: a first portion having a height corresponding to the upper surface of the first pad, and a second portion having a height lower than the upper surface of the first pad and includes corresponding to the recess.

In addition, the upper surface of the first pad and the upper surface of the first portion of the second pad are located lower than the upper surface of the first insulating layer.

In addition, the semiconductor package further comprises a trace disposed on the first insulating layer and connected to at least one of the first pad and the second pad, and wherein the recess of the second pad is closer to the lower surface of the first insulating layer than an upper surface of the trace.

In addition, a width of the recess ranges from 30% to 90% of the width of the second pad.

In addition, a vertical distance between the upper surface of the first insulating layer and the upper surface of the first pad or the second pad ranges from 1 μm to 8 μm.

In addition, the first pad includes a plurality, and a plurality of first openings are formed to vertically overlap each of the plurality of first pads.

In addition, the second pads include a plurality, and one second opening vertically overlaps the plurality of the second pads.

In addition, the second opening vertically overlaps traces disposed between the plurality of second pads.

### Advantageous Effects

The circuit board of the embodiment includes a first insulating layer disposed at a first outermost side and a first circuit pattern layer embedded in an upper surface of the first insulating layer.

The first insulating layer includes a first region and a second region. The first region is a region where the second insulating layer corresponding to a protective layer is disposed, and may mean a n area where the second insulating layer is not disposed. That is, the second insulating layer includes a first opening that partially overlaps the first region in a vertical direction. In addition, the second insulating layer includes a second opening that entirely overlaps the second region in the vertical direction.

In addition, the first circuit pattern layer includes a first pad disposed on the first region of the first insulating layer and a second pad disposed on the second region. In addition, a recess recessed in a downward direction may be formed on the upper surface of the second pad in the embodiment. In addition, the recess formed at the second pad may function as a dam to prevent overflow of connection parts such as solder balls disposed on the second pad. As described above, the embodiment allows a connection part to be stably formed on the second pad, thereby solving the reliability problem caused by overflow of the connection part. For example, the embodiment can solve an electrical reliability problem in which the connection part comes into contact with a neighboring circuit pattern layer as it overflows.

In addition, the embodiment may form a recess not only in the second pad but also in the first pad. That is, like the second pad, a connection part such as a solder ball is disposed on the first pad. At this time, if the recess is formed only on the second pad, a step may occur between the connection part disposed on the first pad and the connection part disposed on the second pad. In addition, the step may cause a problem in which the chip mounted on the connection part is tilted. Accordingly, the embodiment can eliminate the step by forming a recess in the first pad, and thus improve the mounting reliability of the chip.

In addition, the embodiment allows the upper surface of the first insulating layer and the upper surface of the first circuit pattern layer to have a step. For example, the embodiment allows the upper surface of the first circuit pattern layer to be positioned lower than the upper surface of the first insulating layer. Accordingly, the embodiment allows a part of the first insulating layer to serve as a dam to prevent overflow of the connection part, thereby further improving reliability. Furthermore, the embodiment can stably protect traces in the second region where the protective layer is not disposed, thereby improving product reliability.

### DESCRIPTION OF DRAWINGS

FIG. 1 is a view showing a circuit board of a comparative example.

FIG. 2 is a view showing a circuit board according to a first embodiment.

FIG. 3 is an enlarged view for explaining an outermost first circuit pattern layer of FIG. 2.

FIG. 4 is a plan view for explaining an outermost first circuit pattern layer of FIG. 2.

FIG. 5 is a view for explaining a layer structure of a circuit pattern layer of FIG. 2.

FIG. 6 is a view showing a circuit board according to a second embodiment.

FIG. 7 is a view showing a circuit board according to a third embodiment.

FIG. 8 is a view showing a semiconductor package according to an embodiment.

FIGS. 9 to 24 are views showing a circuit board manufacturing method according to an embodiment in order of process.

### MODES OF THE INVENTION

Hereinafter, embodiments of the present invention will be described in detail with reference to the accompanying drawings.

However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

Hereinafter, before explaining a present embodiment, a circuit board of a comparative example compared to this embodiment will be described.

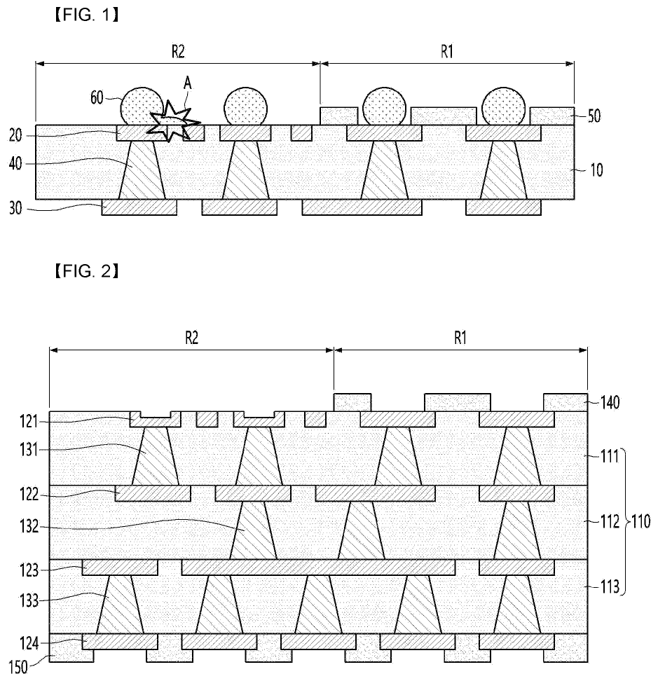

FIG. 1 is a view showing a circuit board of a comparative example.

Referring to FIG. 1, the circuit board of the comparative example is manufactured using a ETS (Embedded Trace Substrate) method.

Accordingly, in the circuit board of the comparative example, at least one of the first and second outermost circuit pattern layers has a structure embedded in the insulating layer.

For example, the circuit board of the comparative example includes an insulating layer 10.

The insulating layer 10 has a plurality of stacked structures or a single-layer structure. A circuit pattern layer is disposed on the surface of the insulating layer 10.

That is, the circuit board of the comparative example includes a first circuit pattern layer 20 disposed on one side of the insulating layer 10 and a second circuit pattern layer 30 disposed on the other side of the insulating layer 10 opposite to the one side.

The first circuit pattern layer 20 is a first outermost circuit pattern layer of the insulating layer 10. For example, the first circuit pattern layer 20 is a circuit pattern layer disposed on an uppermost side of the insulating layer 10.

In addition, the second circuit pattern layer 30 is a second outermost circuit pattern layer of the insulating layer 10. For example, the second circuit pattern layer 30 is a circuit pattern layer disposed on a lowermost side of the insulating layer 10.

At this time, the circuit board of the comparative example has a structure in which one of the first circuit pattern layer 20 and the second circuit pattern layer 30 is embedded in the insulating layer 10.

Specifically, the first circuit pattern layer 20 has a structure embedded in one surface of the insulating layer 10. And, the second circuit pattern layer 30 has a structure that protrudes from the other surface of the insulating layer 10.

At this time, a protective layer 50 is disposed on one side of the insulating layer 10. As an example, the protective layer 50 is a solder resist.

Here, in the circuit board of the comparative example, the insulating layer 10 is divided into a plurality of regions. For example, the insulating layer 10 includes a first region R1 where the protective layer 50 is disposed and a second region R2 other than the first region R1.

And, the first circuit pattern layer 20 is disposed in the first region R1 and the second region R2, respectively. For example, the first circuit pattern layer 20 includes a first pad (not shown) disposed in the first region R1 and a second pad (not shown) disposed in the second region R2.

At this time, the first pad and the second pad refer to mounting pads on which the chip is mounted. That is, in a general circuit board, the mounting pad is disposed not only in the first region R1 where the protective layer 50 is disposed, but also in the second region R2 where the protective layer 50 is not disposed.

And, for chip mounting, a connection part 60 is disposed on the upper surfaces of the first pad and the second pad. For example, the connection part 60 is a solder ball.

Here, the upper surface of the first pad is exposed through an opening (not shown) of the protective layer 50. Accordingly, the connection part 60 disposed on the first pad is disposed in the opening of the protective layer 50. Accordingly, the protective layer 50 may act as a dam to prevent the connection part 60 disposed on the first pad from overflowing.

However, the protective layer 50 as described above is not disposed in the second region R2. Accordingly, unlike the connection part disposed on the first pad, the connection part 60 disposed on the second pad does not have a structure that acts as a dam.

Accordingly, when a certain pressure is applied for chip mounting while the connection part 60 is placed on the second pad, a problem occurs in which the connection part 60 overflows. And, the overflowed connection part generates a short region (A) connected to the neighboring circuit pattern layer.

In addition, in order to solve the above problem, a volume of the connection part 60 disposed on the second pad is reduced. Also, when the volume of the connection part 60 is reduced, the amount of the connection part 60 is not sufficient, resulting in a connection failure in which the chip and the second pad are not electrically connected to each other. In addition, when the volume of the connection part 60 is reduced as described above, a step occurs between the connection part placed on the first pad and the connection part placed on the second pad, and as a result, a reliability problem occurs in which the chip is mounted in an inclined state.

Accordingly, the embodiment provides a circuit board that can prevent overflow of a connection part disposed on ae pad of an outermost circuit pattern layer. Furthermore, the embodiment can improve the reliability of the circuit board by forming a recess that acts as a dam to prevent overflow of the connection part on the pad of the outermost circuit pattern layer disposed in the region where the protective layer is not disposed.

Hereinafter, a circuit board and a semiconductor package according to an embodiment will be described in detail.

### —Electronic Device—

Before describing the embodiment, a semiconductor package having a structure in which a chip is mounted on a circuit board of an embodiment may be included in an electronic device.

At this time, the electronic device includes a main board (not shown). The main board may be physically and/or electrically connected to various components. For example, the main board may be connected to the semiconductor package of the embodiment. Various chips may be mounted on the semiconductor package. Broadly, memory chips such as volatile memory (eg DRAM), non-volatile memory (eg ROM), flash memory, and the like, an application processor chip such as a central processor (eg, CPU), a graphics processor (eg, GPU), a digital signal processor, an encryption processor, a microprocessor, and a microcontroller, and a logic chip such as an analog-to-digital converter or an application-specific IC (ASIC) may be mounted on the semiconductor package.

In addition, the embodiment provides a semiconductor package capable of mounting at least two different types of chips on one substrate while reducing the thickness of the semiconductor package connected to the main board of the electronic device.

In this case, the electronic device may be a smart phone, a personal digital assistant, a digital video camera, a digital still camera, a network system, computer, a monitor, a tablet, a laptop, a netbook, a television, a video game, a smart watch, an automotive, or the like. However, the embodiment is not limited thereto, and may be any other electronic device that processes data in addition to these.

Hereinafter, a circuit board and a semiconductor package including the same according to an embodiment will be described.

### —Circuit Board—

Hereinafter, a circuit board according to an embodiment and a package substrate including the circuit board will be described in detail.

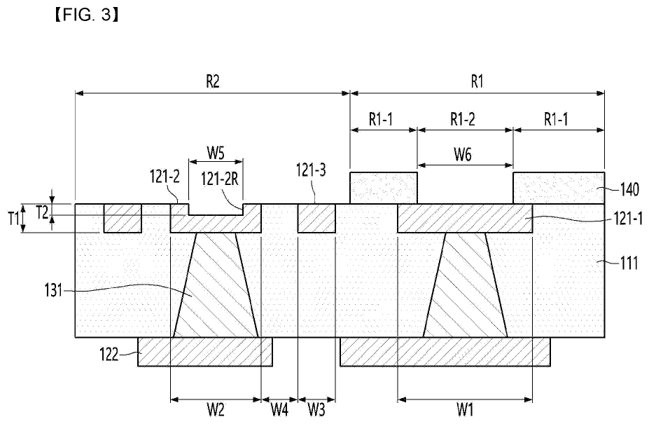

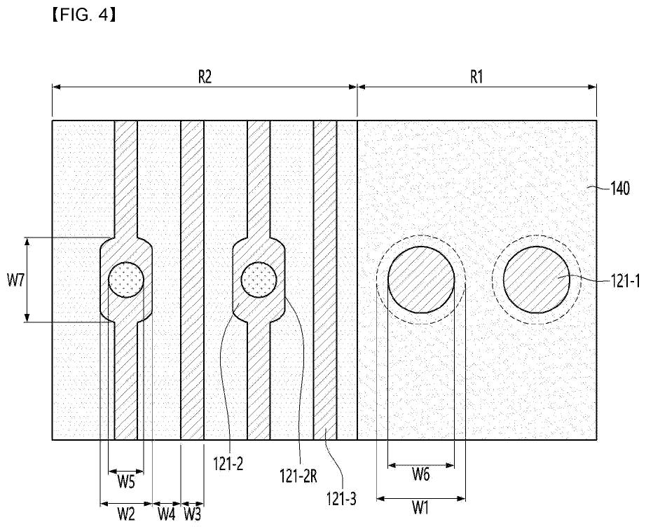

FIG. 2 is a view showing a circuit board according to a first embodiment, FIG. 3 is an enlarged view for explaining an outermost first circuit pattern layer of FIG. 2, FIG. 4 is a plan view for explaining an outermost first circuit pattern layer of FIG. 2, and FIG. 5 is a view for explaining a layer structure of a circuit pattern layer of FIG. 2.

Hereinafter, the circuit board according to the first embodiment will be described in detail with reference to FIGS. 2 to 5.

The circuit board of the embodiment provides a mounting space that allows at least one chip to be mounted. The number of chips mounted on the circuit board of the embodiment may be one, alternatively, there may be two, and alternatively, there may be three or more. For example, one processor chip may be mounted on the circuit board, and alternatively, at least two processor chips performing different functions may be mounted on the circuit board. Alternatively, one memory chip may be mounted along with one processor chip. Alternatively, at least two processor chips and at least one memory chip performing different functions may be mounted.

The circuit board includes an insulating layer 110. The insulating layer 110 has a structure of at least one layer. At this time, in FIG. 2, the circuit board is shown as having a three-layer structure based on the number of insulating layers 110, but the circuit board is not limited to this. For example, the circuit board may have a stacked structure of two or less layers based on the number of insulating layers 110, or alternatively, it may have a stacked structure of four or more layers.

However, for convenience of explanation, hereinafter, the circuit board will be described as having a three-layer structure based on the number of insulating layers 110.

The insulating layer 110 can be composed of a prepreg. The prepreg can be formed by impregnating an epoxy resin or the like into a fiber layer in the form of a fabric sheet, such as a glass fabric woven with glass fiber yarn, and then performing heat compression. However, the embodiment is not limited thereto, and the prepreg constituting the insulating layer 110 can include a fiber layer in the form of a fabric sheet woven with carbon fiber yarn.

For example, the insulating layer 110 can include a resin and a reinforcing fiber disposed in the resin. The resin can be an epoxy resin, but is not limited thereto. The resin is not particularly limited to the epoxy resin, and for example, one or more epoxy groups can be included in the molecule, or alternatively, two or more epoxy groups can be included, or alternatively, four or more epoxy groups can be included. In addition, the resin can include a naphthalene group, for example, can be an aromatic amine type, but is not limited thereto. For example, the resin can be include a bisphenol A type epoxy resin, a bisphenol F type epoxy resin, a bisphenol S type epoxy resin, a phenol novolac type epoxy resin, an alkylphenol novolac type epoxy resin, a biphenyl type epoxy resin, an aralkyl type epoxy resin, dicyclopentadiene type epoxy resin, naphthalene type epoxy resin, naphthol type epoxy resin, epoxy resin of condensate of phenol and aromatic aldehyde having phenolic hydroxyl group, biphenyl aralkyl type epoxy resin, fluorene type epoxy resin resins, xanthene-type epoxy resins, triglycidyl isocyanurate, rubber-modified epoxy resins, phosphorous-based epoxy resins, and the like, and naphthalene-based epoxy resins, bisphenol A-type epoxy resins, and phenol novolac epoxy resins, cresol novolac epoxy resins, rubber-modified epoxy resins, and phosphorous-based epoxy resins. In addition, the reinforcing fiber can include glass fiber, carbon fiber, aramid fiber (e.g., aramid-based organic material), nylon, silica-based inorganic material or titania-based inorganic material. The reinforcing fibers can be arranged in the resin to cross each other in a planar direction.

Meanwhile, the glass fiber, carbon fiber, aramid fiber (e.g., aramid-based organic material), nylon, silica-based inorganic material or titania-based inorganic material can be used.

However, the embodiment is not limited to this, and the insulating layer 110 may include other insulating materials.

For example, the insulating layer 110 may be rigid or flexible. For example, the insulating layer 110 may include glass or plastic. In detail, the insulating layer 110 may include chemically tempered/semi-tempered glass such as soda lime glass or aluminosilicate glass, etc., a tempered or flexible plastic such as polyimide (PI), or polyethylene terephthalate (PET), propylene glycol (PPG), polycarbonate (PC), etc., or sapphire. In addition, the insulating layer 110 may include an optical isotropic film. As an example, the insulating layer 110 may include cyclic olefin copolymer (COC), cyclic olefin polymer (COP), optical isotropic polycarbonate (PC), optical isotropic polymethyl methacrylate (PMMA), or the like. In addition, the insulating layer 110 may be formed of a material including an inorganic filler and an insulating resin. For example, the material constituting the insulating layer 110 may include a resin including a reinforcing material such as an inorganic filler such as silica or alumina together with a thermosetting resin such as an epoxy resin or a thermoplastic resin such as polyimide, specifically, ABF (Ajinomoto Build-up Film), FR-4, BT (Bismaleimide Triazine), PID (Photo Imageable Dielectric Resin), BT, etc.

The insulating layer 110 may include a first insulating layer 111, a second insulating layer 112, and a third insulating layer 113 from an uppermost side.

The first insulating layer 111, the second insulating layer 112, and the third insulating layer 113 may each have a thickness ranging from 10 μm to 100 μm. For example, the first insulating layer 111, the second insulating layer 112, and the third insulating layer 113 may have a thickness ranging from 15 μm to 80 μm. For example, the first insulating layer 111, the second insulating layer 112, and the third insulating layer 113 may each have a thickness ranging from 20 μm to 50 μm.

At this time, the thickness of the first insulating layer 111, the second insulating layer 112, and the third insulating layer 113 may correspond to a distance in a thickness direction between circuit patterns arranged in different layers.

For example, the thickness of the first insulating layer 111 may mean a straight line distance between a lower surface of the first circuit pattern layer 121 and an upper surface of the second circuit pattern layer 122. For example, the thickness of the second insulating layer 112 may mean a straight line distance between a lower surface of the second circuit pattern layer 122 and the third circuit pattern layer 123. For example, the thickness of the third insulating layer 113 may mean a straight line distance between a lower surface of the third circuit pattern layer 123 and the fourth circuit pattern layer 124.

Meanwhile, the first insulating layer 111 may be a first outermost insulating layer disposed at a first outermost side of the circuit board of the embodiment. For example, the first insulating layer 111 may be an uppermost insulating layer disposed at an uppermost side of the circuit board.

In addition, the third insulating layer 113 may be a second outermost insulating layer disposed at a second outermost side opposite to the first insulating layer 111 in the circuit board of the embodiment. For example, the second insulating layer 112 may be a lowermost insulating layer disposed at a lowermost side of the circuit board.

In addition, the second insulating layer 112 may be an inner insulating layer disposed between the first outermost insulating layer and the second outermost insulating layer. At this time, when the circuit board has a layer structure of four or more layers, the inner insulating layer may have a layer structure of two or more layers.

A circuit pattern layer is disposed on the surface of the insulating layer 110.

For example, a first circuit pattern layer 121 is disposed on the upper surface of the first insulating layer 111. For example, the second circuit pattern layer 122 is disposed on the lower surface of the first insulating layer 111 or the upper surface of the second insulating layer 112. For example, the third circuit pattern layer 123 is disposed on the lower surface of the second insulating layer 112 or the upper surface of the third insulating layer 113. For example, a fourth circuit pattern layer 124 is disposed on the lower surface of the third insulating layer 113.

In an embodiment, a circuit board may be manufactured using an Embedded Trace Substrate (ETS) method. Accordingly, at least one of the plurality of circuit pattern layers included in the circuit board may have an ETS structure. For example, a circuit pattern layer disposed on at least one layer among the circuit pattern layers disposed on each layer of the circuit board may have a structure embedded in the surface of the insulating layer. For example, in an embodiment, the circuit pattern layer disposed on the upper surface of the first outermost insulating layer may have an ETS structure. For example, in an embodiment, the first circuit pattern layer 121 disposed on the upper surface of the first insulating layer 111 may have an ETS structure.

Accordingly, the first circuit pattern layer 121 may have a structure embedded in the upper surface of the first insulating layer 111. And, in an embodiment, the second circuit pattern layer 122, third circuit pattern layer 123, and fourth circuit pattern layer 124, excluding the first circuit pattern layer 121 have a structure protruding from the surface of the insulating layer 110.

For example, the first circuit pattern layer 121 may have a structure embedded in the upper surface of the first insulating layer 111. For example, the upper surface of the first circuit pattern layer 121 may be a circuit pattern layer disposed on the first outermost side of the circuit board. Accordingly, the first circuit pattern layer 121 may be exposed to the first outermost side of the circuit board. The first circuit pattern layer 121 may be surrounded by the first insulating layer 111. For example, side and lower surfaces of the first circuit pattern layer 121 may be surrounded by the first insulating layer 111.

Meanwhile, in the first embodiment, the upper surface of the first circuit pattern layer 121 may be positioned on the same plane as the upper surface of the first insulating layer 111. For example, the upper surface of the first circuit pattern layer 121 may be positioned on the same plane as the upper surface of the first insulating layer 111.

At this time, the first circuit pattern layer 121 may include a plurality of pads. For example, the first circuit pattern layer 121 may include a first pad 121-1 and a second pad 121-2. The first pad 121-1 and the second pad 121-2 may be mounting pads. For example, the first pad 121-1 and the second pad 121-2 may be parts where a chip is mounted. For example, the first pad 121-1 and the second pad 121-2 may be parts where connection parts such as solder balls are placed.

For example, the upper surface of the first pad 121-1 may be positioned on the same plane as a portion of the upper surface of the second pad 121-2. For example, the upper surface of the first pad 121-1 may be positioned on a different plane from another portion of the upper surface of the second pad 121-2. For example, the upper surface of the first pad 121-1 may be positioned higher than another portion of the upper surface of the second pad 121-2. For example, a portion of the upper surface of the second pad 121-2 may be positioned higher than another portion of the upper surface of the second pad 121-2. For example, the upper surface of the second pad 121-2 may have a step. For example, the upper surface of the second pad 121-2 may include a concave portion (or recess) that is recessed downward. Preferably, a recess 121-2R may be formed on the upper surface of the second pad 121-2. In addition, a portion of the upper surface of the second pad 121-2 may refer to a portion in which the recess 121-2R is not formed, and another portion of the upper surface of the second pad 121-2 may represent a bottom surface of the recess 121-2R. And, the recess 121-2R of the second pad 121-2 is positioned closer to the lower surface of the first insulating layer than the upper surface of the first pad 121-1.

This will be explained in more detail below.

The second circuit pattern layer 122 may have a structure that protrudes downward from the lower surface of the first insulating layer 111. For example, the second circuit pattern layer 122 may have a structure embedded in the upper surface of the second insulating layer 112. The side and lower surfaces of the second circuit pattern layer 122 may be surrounded by the second insulating layer 112.

For example, the third circuit pattern layer 123 may have a structure that protrudes downward from the lower surface of the second insulating layer 112. For example, the third circuit pattern layer 123 may have a structure embedded in the upper surface of the third insulating layer 113. The side and lower surfaces of the third circuit pattern layer 123 may be surrounded by the third insulating layer 113.

For example, the fourth circuit pattern layer 124 may have a structure that protrudes downward from the lower surface of the third insulating layer 113. For example, the fourth circuit pattern layer 124 may be a circuit pattern layer disposed on the second outermost side of the circuit board. Accordingly, the lower surface of the fourth circuit pattern layer 124 may be exposed to the second outermost side of the circuit pattern layer 121.

Meanwhile, circuit pattern layers including the first circuit pattern layer 121 of the embodiment may include traces and pads. For example, the first circuit pattern layer 121 and the fourth circuit pattern layer 124 disposed on the first and second outermost sides of the circuit board can include a mounting pad on which a chip is mounted or a terminal pad connected to an external board. In addition, the first circuit pattern layer 121 and the fourth circuit pattern layer 124 can include traces, which are long wires connected to the mounting pad or terminal pad.

The circuit pattern layers described above may be formed of at least one metal material selected from among gold (Au), silver (Ag), platinum (Pt), titanium (Ti), tin (Sn), copper (Cu), and zinc (Zn). In addition, the circuit pattern layers may be formed of paste or solder paste including at least one metal material selected from among gold (Au), silver (Ag), platinum (Pt), titanium (Ti), tin (Sn), copper (Cu), and zinc (Zn), which are excellent in bonding force. Preferably, the first circuit pattern layer 121, the second circuit pattern layer 122, the third circuit pattern layer 123, and the fourth circuit pattern layer 124 may be formed of copper (Cu) having high electrical or thermal conductivity and a relatively low cost.

Each of the first circuit pattern layer 121, the second circuit pattern layer 122, the third circuit pattern layer 123, and the fourth circuit pattern layer 124 can have a thickness T1 in a range of 5 μm to 20 μm. For example, each of the first circuit pattern layer 121, the second circuit pattern layer 122, the third circuit pattern layer 123, and the fourth circuit pattern layer 124 can have a thickness in a range of 6 μm to 17 μm. Each of the first circuit pattern layer 121, the second circuit pattern layer 122, the third circuit pattern layer 123, and the fourth circuit pattern layer 124 can have a thickness in a range of 7 μm to 16 μm. When the thickness of each of the first circuit pattern layer 121, the second circuit pattern layer 122, the third circuit pattern layer 123, and the fourth circuit pattern layer 124 is less than 5 μm, a resistance of the circuit pattern layer increases, which may reduce signal transmission efficiency. For example, when the thickness of each of the first circuit pattern layer 121, the second circuit pattern layer 122, the third circuit pattern layer 123, and the fourth circuit pattern layer 124 is less than 5 μm, signal transmission loss may increase. For example, when the thickness of each of the first circuit pattern layer 121, the second circuit pattern layer 122, the third circuit pattern layer 123, and the fourth circuit pattern layer 124 exceeds 20 μm, a line width of the circuit pattern layers increases, and thus an overall volume of the circuit board may increase.

Meanwhile, the first circuit pattern layer 121 of the embodiment may be a fine pattern. In addition, correspondingly, the second circuit pattern layer 122, the third circuit pattern layer 123, and the fourth circuit pattern layer 124 may also be fine patterns. However, in the embodiment, the first circuit pattern layer 121 includes a chip mounting portion where a chip in a semiconductor package is mounted. In addition, the first circuit pattern layer 121 may include a mounting pad on which at least one application processor chip is mounted. For example, the first circuit pattern layer 121 may include a mounting pad on which at least two application processor chips are mounted. Accordingly, the first circuit pattern layer 121 may include a fine pattern. However, features of the first circuit pattern layer 121 described below may be equally applied to the second circuit pattern layer 122, the third circuit pattern layer 123, and the fourth circuit pattern layer 124. However, for convenience of explanation, only the first circuit pattern layer 121 will be described.

A detailed description of the first circuit pattern layer 121 is as follows.

The first circuit pattern layer 121 includes the first pad 121-1 and the second pad 121-2 as described above. In addition, the first circuit pattern layer 121 includes a trace 121-3. The trace 121-3 may represent a long wire that is connected to the first pad 121-1 and/or the second pad 121-2 and thereby transmits an electrical signal.

At this time, the first pad 121-1 and the second pad 121-2 perform substantially the same function, but are distinguished by being disposed in different regions on the upper surface of the first insulating layer 111.

Specifically, the first insulating layer 111 may include a plurality of regions.

For example, the first insulating layer 111 may include a first region R1 and a second region R2. The first region R1 and the second region R2 may be distinguished by a first protective layer 140 disposed on the upper surface of the first insulating layer 111. The first protective layer 140 may also be referred to as an ‘insulating layer’. The first region R1 may refer to a region in which a first pad is disposed, with at least a portion of the upper surface vertically overlapping with the first protective layer 140. And, the second region R2 may refer to a region in which a second pad whose upper surface does not overlap vertically with the first protective layer 140 is disposed.

For example, the first region R1 may refer to a region where the first protective layer 140 is disposed. For example, the second region R2 may mean a region other than the first region R1. For example, the second region R2 may mean a region in which the first protective layer 140 is not disposed. In other words, the first region R1 may mean an SR (Solder Resist) masking region where the first protective layer 140 is disposed. And, the second region R2 may mean a non-SR region in which the first protective layer 140 is not disposed.

That is, the first protective layer 140 includes a plurality of openings. For example, the first protective layer 140 may include a first opening that partially vertically overlaps the first region R1. For example, the first protective layer 140 may include a second opening that entirely vertically overlaps the second region R2. Also, the first protective layer 140 may not be entirely disposed in the second region R2 where the second opening is formed.

That is, an outermost side (for example, a surface of an outermost insulating layer) of a general circuit board includes a first region R1 where solder resist is disposed and a second region other than the first region R1.

And, the first pad 121-1 of the first circuit pattern layer 121 may refer to a pattern disposed in the first region R1. For example, the first pad 121-1 of the first circuit pattern layer 121 may refer to a mounting pad disposed in the first region R1.

In addition, the second pad 121-2 of the first circuit pattern layer 121 may refer to a pattern disposed in the second region. For example, the second pad 121-2 of the first circuit pattern layer 121 may refer to a mounting pad disposed in the second region R2.

In addition, the trace 121-3 of the first circuit pattern layer 121 may mean a signal line connected to the first pad 121-1 and/or the second pad 121-2. The traces 121-3 of the first circuit pattern layer 121 may be disposed in the first region R1 and in the second region R2. Preferably, the traces 121-3 of the first circuit pattern layer 121 may be disposed in both the first region R1 and the second region R2.

A width W1 of the first pad 121-1 of the first circuit pattern layer 121 may satisfy a range of 50 μm to 130 μm. For example, the width W1 of the first pad 121-1 of the first circuit pattern layer 121 may be satisfy a range of 60 μm to 115 μm. For example, the width W1 of the first pad 121-1 of the first circuit pattern layer 121 may satisfy a width of 70 μm to 110 μm. In this case, the width W1 may mean any one of a width in a width direction, a width in a longitudinal direction, and a width in a diagonal direction between the width direction and the longitudinal direction of the first pad 121-1 in the plane of the circuit board. Preferably, the first pad 121-1 of the first circuit pattern layer 121 may have a first shape. For example, the first pad 121-1 of the first circuit pattern layer 121 may have a circular shape. Accordingly, the width in the width direction, the width in the longitudinal direction, and the width in the diagonal direction of the first pad 121-1 of the first circuit pattern layer 121 may be substantially the same.

Meanwhile, the width W2 of the second pad 121-2 of the first circuit pattern layer 121 may be different from the width W1 of the first pad 121-1. The width W2 of the second pad 121-2 may mean the width in the longitudinal direction or the width in the width direction. Preferably, the second pad 121-2 may have a second shape. For example, the second pad 121-2 may have a second shape different from the first shape of the first pad 121-1. As an example, the second pad 121-2 may have an oval shape.

Accordingly, the width W2 of the second pad 121-2 in the first direction may satisfy a range of 20 μm to 80 μm. For example, the width W2 of the second pad 121-2 in the first direction may be satisfy a range of 25 μm to 75 μm. For example, the width W2 of the second pad 121-2 in the first direction may be satisfy a range of 30 μm to 60 μm.

In addition, the width W7 of the second pad 121-2 in the second direction may satisfy a range of 50 μm to 130 μm. For example, the width W7 of the second pad 121-2 in the second direction may satisfy a range of 60 μm to 115 μm. For example, the width W7 of the second pad 121-2 in the second direction may satisfy a range of 70 μm to 110 μm.

As described above, the embodiment allows the second pad 121-2 to have an oval shape in the second region R2 where the first protective layer 140 is not disposed, and it is possible to improve circuit density in the second region R2. Furthermore, the first protective layer 140 is not disposed in the second region R2, and as a result, damage may occur to the trace 121-3 disposed in the second region R2. At this time, in the embodiment, the shape of the second pad 121-2 is oval, so that the width in the second direction is narrower than the width in the first direction, as described above. Through this, the embodiment can further secure a spacing between the second pad 121-2 and the trace 121-3 in the second direction, and accordingly, damage to the trace 121-3 can be minimized.

A line width W3 of the trace 121-3 of the first circuit pattern layer 121 may be 7 μm or less. For example, the line width W3 of the trace 121-3 of the first circuit pattern layer 121 may be 6 μm or less. For example, the line width W3 of the trace 121-3 of the first circuit pattern layer 121 may be 5 μm or less. For example, the line width W3 of the trace 121-3 of the first circuit pattern layer 121 may range from 1 μm to 7 μm. For example, the line width W3 of the trace 121-3 of the first circuit pattern layer 121 may range from 1.5 mm to 6.5 μm. For example, the line width W3 of the trace 121-3 of the first circuit pattern layer 121 may range from 2 μm to 6 μm.

In addition, the traces 121-3 of the first circuit pattern layer 121 may have a specific spacing W4. The spacing W4 may mean a spacing between the trace 121-3 and the first pad 121-1 or the trace 121-3 and the second pad 121-2. In addition, the spacing W4 may mean a spacing between a plurality of traces.

The spacing W4 between the traces 121-3 may be 7 μm or less. For example, the spacing W4 between the traces 121-3 of the first circuit pattern layer 121 may be 6 μm or less. For example, the spacing W4 between the traces 121-3 of the first circuit pattern layer 121 may be 5 μm or less. For example, the spacing W4 between the traces 121-3 of the first circuit pattern layer 121 may range from 1 μm to 7 μm. For example, the spacing W4 between the traces 121-3 of the first circuit pattern layer 121 may range from 1.5 μm to 6.5 μm. For example, the spacing W4 of the traces 121-3 may range from 2 μm to 6 μm.

However, in an embodiment, the line width W3 of the first circuit pattern layer 121 may be greater than the spacing W4. For example, the trace 121-3 of the first circuit pattern layer 121 has a thickness of 7 μm or less. At this time, in a general circuit board, there is a limit to further reducing the line width of the trace 121-3 in a range described above. Accordingly, in order to increase the density of the first circuit pattern layer 121 within a limited space, it is important to reduce the spacing between the traces 121-3 of the first circuit pattern layer 121 rather than the line width of the traces 121-3. At this time, in the embodiment, the spacing W4 between the traces 121-3 of the first circuit pattern layer 121 is smaller than the line width W3 of the trace 121-3. Accordingly, the embodiment can increase the density of the first trace 121-3 within a limited space even while maintaining the line width of the trace 121-3 at a certain level, and as a result, the overall volume of the circuit board can be reduced. At this time, as described above, the spacing W4 of the traces 121-3 is smaller than the line width W3, which can be achieved by the characteristics of the circuit board manufacturing method described below.

That is, in the embodiment, in a process of forming the first circuit pattern layer 121, an additional process for miniaturizing the first circuit pattern layer 121 is performed. For example, the first circuit pattern layer 121 can be achieved by performing electrolytic plating within the opening of a mask such as a dry film. At this time, when the spacing W4 of the traces 121-3 is lowered above a certain level, the contact area between the dry film and the seed layer (described later) decreases, and this causes the dry film to peel off from the seed layer. Therefore, in the related art, due to a problem of adhesion between the dry film and the seed layer, the spacing W4 between the traces 121-3 had to be secured at a certain level or higher. That is, the spacing W4 of the trace 121-3 corresponds to the contact area between the dry film and the seed layer. Accordingly, in the related art, the spacing W4 had to be increased to increase the contact area. Unlike this, the embodiment additionally proceeds with the process of curing the dry film while ensuring that the spacing W4 is smaller than the line width W3, and it is possible to improve adhesion between the dry film and the seed layer. In other words, in the embodiment, even if the spacing W4 is smaller than the line width W3, the dry film can secure adhesion to the seed layer through a curing process, and accordingly, the reliability problem of the dry film falling off from the seed layer can be solved.

As described above, the first circuit pattern layer 121 in the embodiment includes a trace 121-3, and the trace 121-3 has a line width W3 of 7 μm or less and a spacing W4 of 7 μm or less. At this time, the spacing W4 of the first circuit pattern layer 121 is smaller than the line width W3 of the first circuit pattern layer 121. Accordingly, the embodiment enables miniaturization of the first circuit pattern layer 121 while ensuring reliability of the first circuit pattern layer 121, and accordingly, the density of the first circuit pattern layer 121 within a limited space can be improved. Furthermore, in the embodiment, as the miniaturization of the first circuit pattern layer 121 is achieved, at least two or more application processor chips can be mounted on the first circuit pattern layer 121, and accordingly, the overall volume of the semiconductor package can be reduced.

Meanwhile, the second pad 121-2 of the first circuit pattern layer 121 may include a recess 121-2R. The recess 121-2R may be formed by removing a portion of the upper surface of the second pad 121-2. For example, a recess 121-2R recessed downward may be formed on the upper surface of the second pad 121-2. In addition, the recess 121-2R can prevent overflow of connection parts such as solder balls in the semiconductor package. For example, the recess 121-2R may serve as a dam to confine a connection part such as a solder ball placed on the second pad 121-2, and accordingly, it is possible to solve the problem of the solder balls overflowing into the surrounding area during the reflow process of the solder balls.

That is, as described above, in the embodiment, the second pad 121-2 of the first circuit pattern layer 121 is formed in the second region R2 where the first protective layer 140 is not formed.

At this time, the first protective layer 140 includes an opening.

For example, the first region R1 can include a first-first region R1-1 where the first protective layer 140 is disposed, and a first-second region R1-2 corresponding to the opening of the first protective layer 140. And, a portion of the first pad 121-1 of the first circuit pattern layer 121 is partially disposed in the first-first region R1-1, and the remaining portion of the first pad 121-1 of the first circuit pattern layer 121 may be disposed in the first-second region R1-2. That is, a portion of the upper surface of the first pad 121-1 of the first circuit pattern layer 121 is disposed in the first-first region R1-1, and accordingly, it may be covered by the first protective layer 140. In addition, the remaining portion of the upper surface of the first pad 121-1 of the first circuit pattern layer 121 is disposed in the first-second region R1-2, and accordingly, it may be exposed through the opening of the first protective layer 140.

A width W6 of the opening of the first protective layer 140 may be 70% to 95% of the width W1 of the second pad 121-1. The width W6 of the opening of the first protective layer 140 may be 75% to 92% of the width W1 of the second pad 121-1. The width W6 of the opening of the first protective layer 140 may be 80% to 90% of the width W1 of the second pad 121-1.

Also, when a connection part such as a solder ball is placed on the first pad 121-1, the solder ball can be stably seated within the opening of the first protective layer 140. For example, the first protective layer 140 may act as a dam to prevent overflow of connection parts such as solder balls disposed on the first pad 121-1.

Accordingly, there is no reliability issue with the first pad 121-1 disposed in the first region R1.

In contrast, the first protective layer 140 serving as a dam as described above is not disposed in the second region R2. Accordingly, when a connection part such as a solder ball is placed on the second pad 121-2 disposed in the second region R2, as there is no structure that serves to confine the surroundings of the connection part, a problem of overflow of the connection part may occur.

Accordingly, in the embodiment, a recess 121-2R is formed by processing a portion of the upper surface of the second pad 121-2 disposed in the second region R2. In addition, the recess 121-2R may function as a dam to confine a connection part such as a solder ball disposed on the second pad 121-2. Accordingly, the embodiment can solve the problem of overflow of connection parts such as solder balls in a region where the first protective layer 140 is not disposed.

The recess 121-2R may have a width W5 of 30% to 90% of the width W2 of the second pad 121-2 in the first direction. For example, the recess 121-2R may have a width W5 of 35% to 85% of the width W2 of the second pad 121-2 in the first direction. For example, the recess 121-2R may have a width W5 of 40% to 80% of the width W2 of the second pad 121-2 in the first direction. For example, the width W5 of the recess 121-2R may have a range of 10 μm to 70 μm. For example, the width W5 of the recess 121-2R may have a range of 15 μm to 65 μm. For example, the width W5 of the recess 121-2R may be have a range of 20 μm to 50 μm.

When the width W5 of the recess 121-2R is less than 30% of the width W2 of the second pad 121-2 in the first direction or less than 10 μm, a problem may occur in which a connection part such as a solder ball disposed on the second pad 121-2 is not stably confined by the groove 121-2R. For example, when the width W5 of the recess 121-2R is less than 30% of the width W2 of the second pad 121-2 in the first direction or less than 10, it may be difficult for the recess 121-2R to properly implement the role of a dam that confines a connection part such as a solder ball disposed on the second pad 121-2.

When the width W5 of the recess 121-2R is greater than 90% of the width W2 of the second pad 121-2 in the first direction or greater than 70 μm, as the thickness of the entire region of the second pad 121-2 is reduced, the resistance of the second pad 121-2 increases, which may result in increased signal transmission loss.

Meanwhile, the recess 121-2R may be formed to have a certain depth T2 in the second pad 121-2. At this time, the depth T2 of the recess 121-2R may satisfy 20% to 90% of the thickness T1 of the second pad 121-2. For example, the depth T2 of the recess 121-2R may satisfy 25% to 85% of the thickness T1 of the second pad 121-2. For example, the depth T2 of the recess 121-2R may satisfy 30% to 80% of the thickness T1 of the second pad 121-2.

At this time, when the depth T2 of the recess 121-2R is less than 20% of the thickness T1 of the second pad 121-2, a problem may occur in which the groove 121-2R does not properly perform its function as a dam. For example, when the depth T2 of the recess 121-2R is greater than 90% of the thickness T1 of the second pad 121-2, a problem may occur in which the second pad 121-2 is disconnected due to the groove 121-2R. For example, when the depth T2 of the groove 121-2R is greater than 90% of the thickness T1 of the second pad 121-2, a problem may occur in which the recess 121-2R penetrates the second pad 121-2, and as a result, it may be difficult to properly implement the function of the second pad 121-2.

The circuit board of the embodiment includes vias.

The via penetrates the insulating layer 110 included in the circuit board of the embodiment, and thus can electrically connect circuit pattern layers arranged in different layers. At this time, the via may be formed to penetrate only one insulating layer, or alternatively, it may be formed to commonly penetrate at least two or more insulating layers.

For example, the circuit board includes a first via 131. The first via 131 may be formed penetrating the first insulating layer 111. The first via 131 may electrically connect the first circuit pattern layer 121 and the second circuit pattern layer 122. For example, the upper surface of the first via 131 may be directly connected to the lower surface of the first circuit pattern layer 121. For example, the lower surface of the first via 131 may be directly connected to the upper surface of the second circuit pattern layer 122. In addition, the first circuit pattern layer 121 and the second circuit pattern layer 122 may be electrically connected to each other through the first via 131 to transmit signals.

For example, the circuit board includes a second via 132. The second via 132 may be formed to penetrate the second insulating layer 112. The second via 132 may electrically connect the second circuit pattern layer 122 and the third circuit pattern layer 123. For example, the upper surface of the second via 132 may be directly connected to the lower surface of the second circuit pattern layer 122. For example, the lower surface of the second via 132 may be directly connected to the upper surface of the third circuit pattern layer 123. Accordingly, the second circuit pattern layer 122 and the third circuit pattern layer 123 are directly electrically connected to each other through the second via 132 and can transmit signals.

For example, the circuit board includes a third via 133. The third via 133 may be formed penetrating the third insulating layer 113. The third via 133 may electrically connect the third circuit pattern layer 123 and the fourth circuit pattern layer 124. For example, the upper surface of the third via 133 may be directly connected to the lower surface of the third circuit pattern layer 123. For example, the lower surface of the third via 133 may be directly connected to the upper surface of the fourth circuit pattern layer 124. Accordingly, the third circuit pattern layer 123 and the fourth circuit pattern layer 124 may be electrically connected to each other and transmit signals.

Meanwhile, the vias of the circuit board including the first via 131, the second via 132, and the third via 133 may be formed by filling the inside of via holes passing through the insulating layer 110 with a conductive material.

The via hole may be formed by any one of mechanical, laser, and chemical processing. When the via hole is formed by mechanical processing, a method such as milling, drilling and routing may be used, when the via hole is formed by laser processing, a method of UV or CO₂ laser may be used, when the via hole is formed by chemical processing, a chemical including amino silane, ketones, or the like may be used.

Meanwhile, the laser processing is a cutting method in which a part of a material is melted and evaporated by concentrating optical energy at a surface to take a desired shape. Complex formation by a computer program may be easily processed, and composite materials which are difficult to cut by other methods may be processed.

In addition, processing using the laser has the advantage that the cutting diameter is possible up to a minimum of 0.005 mm and the thickness range that can be processed is wide.

As the laser processing drill, it is preferable to use a YAG (Yttrium Aluminum Garnet) laser, a CO2 laser, or an ultraviolet (UV) laser. The YAG laser is a laser that can process both the copper foil layer and the insulating layer, and the CO2 laser is a laser that can only process the insulating layer.

When the via hole is formed, the via may be formed by filling the inside of the through hole with a conductive material. The metal material forming the via may be any one selected from among copper (Cu), silver (Ag), tin (Sn), gold (Au), nickel (Ni), and palladium (Pd). In addition, the conductive material may be filled by any one of electroless plating, electroplating, screen printing, sputtering, evaporation, ink jetting, and dispensing, or a combination thereof.

Meanwhile, the circuit board of the embodiment may include a first protective layer 140 and a second protective layer 150. The first protective layer 140 and the second protective layer 150 may be disposed on the outermost side of the circuit pattern layer 121.

For example, the first protective layer 140 may be disposed on the first outermost or uppermost side of the circuit board. For example, the first protective layer 140 may be disposed on the upper surface of the first insulating layer 111. For example, the second protective layer 150 may be disposed on the second outermost or lowermost side of the circuit board. For example, the second protective layer 150 may be disposed on the lower surface of the third insulating layer 113.

The second protective layer 150 may include at least one opening (not shown).

For example, the second protective layer 150 may have an opening exposing the lower surface of the fourth circuit pattern layer 124. For example, the second protective layer 150 can have an opening that exposes a region on the lower surface of the fourth circuit pattern layer 124 where solder balls are later placed (for example, a terminal pad portion connected to an external substrate).

At this time, although not shown in the drawing, a surface treatment layer (not shown) may be disposed on the lower surface of the fourth circuit pattern layer 124 exposed through the opening of the second protective layer 150. The surface treatment layer may be formed to improve soldering characteristics while preventing corrosion and corrosion of the fourth circuit pattern layer 124 exposed through the second protective layer 150.

The surface treatment layer may be an Organic Solderability Preservative (OSP) layer. For example, the surface treatment layer may be an organic layer formed of an organic material such as benzimidazole coated on the lower surface of the fourth circuit pattern layer 124.

However, the embodiment is not limited to this. For example, the surface treatment layer may be a plating layer. For example, the surface treatment layer may include at least one of a nickel (Ni) plating layer, a palladium (Pd) plating layer, and a gold (Au) plating layer. In addition, the surface treatment layer may be exposed through the first protective layer 140 or may be formed on the upper surface of the first circuit pattern layer 121 where the first protective layer 140 is not disposed.

Meanwhile, in the circuit board in the embodiment, a certain level of surface roughness may be provided to the circuit pattern layer.

At this time, in the embodiment, the surface roughness of the first circuit pattern layer 121 can be different from surface roughness of the second circuit pattern layer 122, the third circuit pattern layer 123, and the fourth circuit pattern layer 124. For example, the first circuit pattern layer 121 in the embodiment includes a fine pattern. For example, the first circuit pattern layer 121 in the embodiment includes a chip mounting portion connected to the chip, and accordingly, miniaturization is required for connection to the chip within a limited space. In addition, the second circuit pattern layer 122, the third circuit pattern layer 123, and the fourth circuit pattern layer 124 are also required to be miniaturized, but it is not required to be as refined as the first circuit pattern layer 121.

Accordingly, the embodiment applies different pretreatment conditions to each circuit pattern layer in the pretreatment process performed to improve the adhesion between the insulating layer and the circuit pattern layer.

For example, the first circuit pattern layer 121 includes a fine pattern, and accordingly, preprocessing is performed by applying lower preprocessing conditions than those of the second circuit pattern layer 122, third circuit pattern layer 123, and fourth circuit pattern layer 124. For example, when the preprocessing conditions of the first circuit pattern layer 121 may be the same as those of the second circuit pattern layer 122, the third circuit pattern layer 123, and the fourth circuit pattern layer 124, reliability problems such as collapse of the fine circuit pattern layer may occur. Therefore, in the embodiment, the surface roughness of the first circuit pattern layer 121 is smaller than the surface roughness of the second circuit pattern layer 122, the third circuit pattern layer 123, and the fourth circuit pattern layer 124.

For example, a 10-point average surface roughness (Rz) of the first circuit pattern layer 121 can have a range of 0.01 μm to 0.5 μm. In addition, the second circuit pattern layer 122, the third circuit pattern layer 123, and the fourth circuit pattern layer 124 have a 10-point average surface roughness (Rz) greater than that of the first circuit pattern layer 121.

When the 10-point average surface roughness (Rz) of the first circuit pattern layer 121 is less than 0.01 μm, adhesion between the first circuit pattern layer 121 and the first insulating layer 111 decreases, and accordingly, a problem may occur in which the first circuit pattern layer 121 is separated from the first insulating layer 111. When the 10-point average surface roughness (Rz) of the first circuit pattern layer 121 is greater than 0.5 μm, as the skin effect on the surface of the first circuit pattern layer 121 increases, signal transmission loss may increase.

Meanwhile, in an embodiment, the circuit pattern layer and vias may have a multiple layer structure. However, in the embodiment, the first circuit pattern layer 121 of the circuit pattern layers has an ETS structure, and accordingly, the first circuit pattern layer 121 having an ETS structure has a different layer structure from other circuit pattern layers or vias.

For example, the first circuit pattern layer 121 may have a different layer structure from the second circuit pattern layer 122, the third circuit pattern layer 123, and the fourth circuit pattern layer 124. For example, the first circuit pattern layer 121 may have a smaller number of layers than the number of layers of the second circuit pattern layer 122, the third circuit pattern layer 123, and the fourth circuit pattern layer 124.

For example, the first circuit pattern layer 121 may include only an electrolytic plating layer. Alternatively, the second circuit pattern layer 122, the third circuit pattern layer 123, and the fourth circuit pattern layer 124 may each include a seed layer and an electrolytic plating layer. For example, the second circuit pattern layer 122 may include a seed layer 122-1 and an electrolytic plating layer 122-2. For example, the third circuit pattern layer 123 may include a seed layer 123-1 and an electrolytic plating layer 123-2. For example, the fourth circuit pattern layer 124 may include a seed layer 124-1 and an electrolytic plating layer 124. In addition, correspondingly, vias included in the circuit board may include a seed layer and an electrolytic plating layer. For example, the first via 131 may include a seed layer 131-1 and an electrolytic plating layer 131-2. For example, the second via 132 may include a seed layer 132-1 and an electrolytic plating layer 132-2. For example, the third via 133 may include a seed layer 133-1 and an electrolytic plating layer 133-2.

### Variation Example

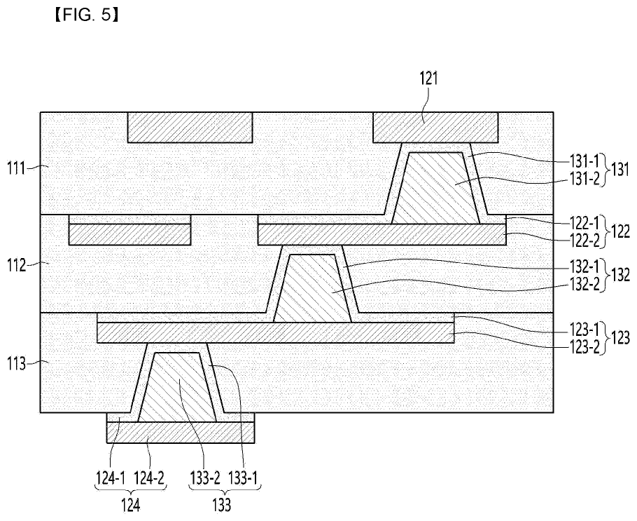

FIG. 6 is a view showing a modified example of the circuit board of FIG. 2.

Referring to FIG. 6, the circuit board may include an insulating layer, a circuit pattern layer, a via, and a protective layer.

At this time, in the circuit board of FIG. 6, a part that is different from the circuit board of FIG. 2 is in the first pad 121-1.

That is, in the circuit board of FIG. 2, no recess was formed in the first pad 121-1. For example, the first pad 121-1 is formed in the region where the first protective layer 140 is disposed, and Accordingly, because the first protective layer 140 functions as a dam, a recess shape is not necessary.

Unlike this, in this modified example, a recess 121-1R similar to the recess formed on the upper surface of the second pad 121-2 is formed on the upper surface of the first pad 121-1.

That is, as shown in FIG. 2, when the recess is formed only on the upper surface of the second pad 121-2, a height difference (e.g., step difference) may occur between the connection part disposed on the first pad 121-1 and the connection part disposed on the second pad 121-2. For example, a portion of the connection part disposed on the second pad 121-2 fills the recess formed in the second pad 121-2. Accordingly, the height of the connection part disposed on the second pad 121-2 may be lower than the height of the connection part disposed on the first pad 121-1.

Accordingly, in this modified example, in order to solve the above problem, a recess 121-1R corresponding to the second pad 121-2 is formed in the first pad 121-1.

Therefore, according to FIG. 5, each of the first pad 121-1 and the second pad 121-2 has a structure in which a recess is formed. Accordingly, the height difference between the connection part placed on the first pad 121-1 and the connection part placed on the second pad 121-2 can be resolved, and accordingly, chip mounting reliability can be improved.

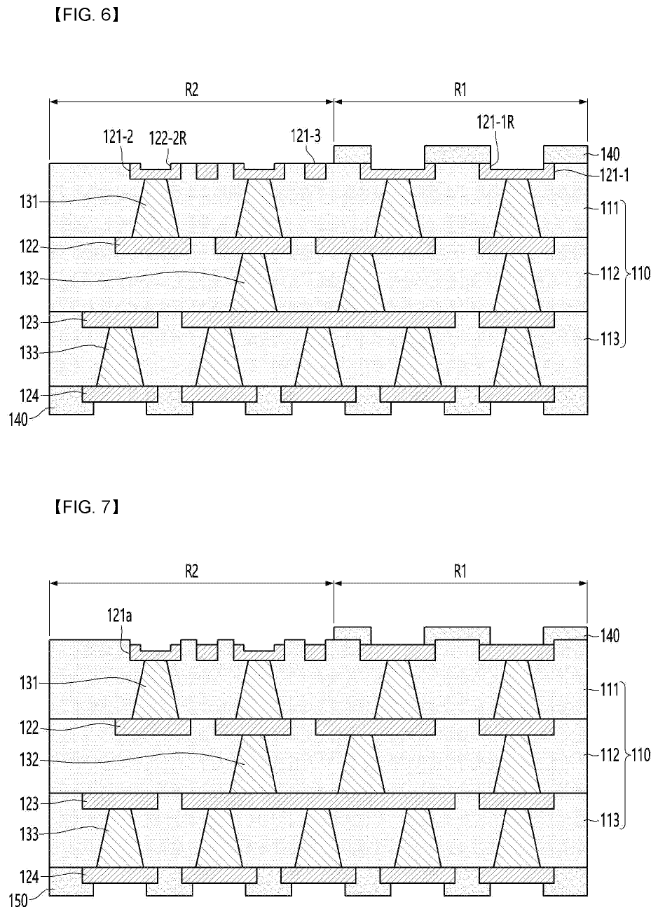

FIG. 7 is a view showing another modified example of the circuit board of FIG. 2.

Referring to FIG. 7, the circuit board may include an insulating layer, a circuit pattern layer, a via, and a protective layer.

At this time, in the circuit board of FIG. 7, a part that is different from the circuit board of FIG. 2 is in the first circuit pattern layer 121a.

For example, the upper surface of the first circuit pattern layer 121 in FIG. 2 is disposed on the same plane as the upper surface of the first insulating layer 111.

Alternatively, a step may be formed between the first circuit pattern layer 121a and the first insulating layer 111 in FIG. 7. For example, a recess may be formed in the first insulating layer 111, and the first circuit pattern layer 121a may be disposed within the recess of the first insulating layer 111. At this time, the first circuit pattern layer 121a may have a thickness smaller than the depth of the recess of the first insulating layer. Accordingly, the upper surface of the first circuit pattern layer 121a may be positioned lower than the upper surface of the first insulating layer 111.

Accordingly, in the embodiment, a portion of the first insulating layer 111 functions as a dam on the second pad 121-2 constituting the first circuit pattern layer 121a, and accordingly, reliability can be further improved. Furthermore, the embodiment includes traces of the first circuit pattern layer 121a placed in the second region R2. At this time, the trace may be a fine pattern. Also, when the trace is placed on the same plane as the surface of the first insulating layer 111, damage to the trace may occur in various environments. Accordingly, the embodiment creates a step between the first insulating layer 111 and the first circuit pattern layer 121a so that the first circuit pattern layer 121a can be stably protected.

Meanwhile, the step between the upper surface of the first insulating layer 111 and the upper surface of the first circuit pattern layer 121a may range from 1 μm to 8 μm. For example, the step between the upper surface of the first insulating layer 111 and the upper surface of the first circuit pattern layer 121a may range from 2 μm to 7 μm. For example, the step between the upper surface of the first insulating layer 111 and the upper surface of the first circuit pattern layer 121a may range from 3 μm to 6 μm.

When the step between the upper surface of the first insulating layer 111 and the first circuit pattern layer 121a is less than 1 μm, the recess of the first insulating layer 111 may not properly perform the dam role as described above. In addition, when the step between the upper surface of the first insulating layer 111 and the first circuit pattern layer 121a is less than 1 μm, traces placed in the second region R2 may not be reliably protected. In addition, when the step between the upper surface of the first insulating layer 111 and the first circuit pattern layer 121a is greater than 8 μm, there may be a problem where the thickness of the circuit board increases by the step. In addition, when the step between the upper surface of the first insulating layer 111 and the upper surface of the first circuit pattern layer 121a is greater than 8 μm, the thickness of the first circuit pattern layer 121a, which is initially formed, must be increased by the step, which causes the manufacturing process to become complicated and the manufacturing cost to increase.

The circuit board of the embodiment includes a first insulating layer disposed at a first outermost side and a first circuit pattern layer embedded in an upper surface of the first insulating layer.

The first insulating layer includes a first region and a second region. The first region is a region where the second insulating layer corresponding to a protective layer is disposed, and may mean a n area where the second insulating layer is not disposed. That is, the second insulating layer includes a first opening that partially overlaps the first region in a vertical direction. In addition, the second insulating layer includes a second opening that entirely overlaps the second region in the vertical direction.

In addition, the first circuit pattern layer includes a first pad disposed on the first region of the first insulating layer and a second pad disposed on the second region. In addition, a recess recessed in a downward direction may be formed on the upper surface of the second pad in the embodiment. In addition, the recess formed at the second pad may function as a dam to prevent overflow of connection parts such as solder balls disposed on the second pad. As described above, the embodiment allows a connection part to be stably formed on the second pad, thereby solving the reliability problem caused by overflow of the connection part. For example, the embodiment can solve an electrical reliability problem in which the connection part comes into contact with a neighboring circuit pattern layer as it overflows.

In addition, the embodiment may form a recess not only in the second pad but also in the first pad. That is, like the second pad, a connection part such as a solder ball is disposed on the first pad. At this time, if the recess is formed only on the second pad, a step may occur between the connection part disposed on the first pad and the connection part disposed on the second pad. In addition, the step may cause a problem in which the chip mounted on the connection part is tilted. Accordingly, the embodiment can eliminate the step by forming a recess in the first pad, and thus improve the mounting reliability of the chip.

In addition, the embodiment allows the upper surface of the first insulating layer and the upper surface of the first circuit pattern layer to have a step. For example, the embodiment allows the upper surface of the first circuit pattern layer to be positioned lower than the upper surface of the first insulating layer. Accordingly, the embodiment allows a part of the first insulating layer to serve as a dam to prevent overflow of the connection part, thereby further improving reliability. Furthermore, the embodiment can stably protect traces in the second region where the protective layer is not disposed, thereby improving product reliability.

### —Semiconductor Package—

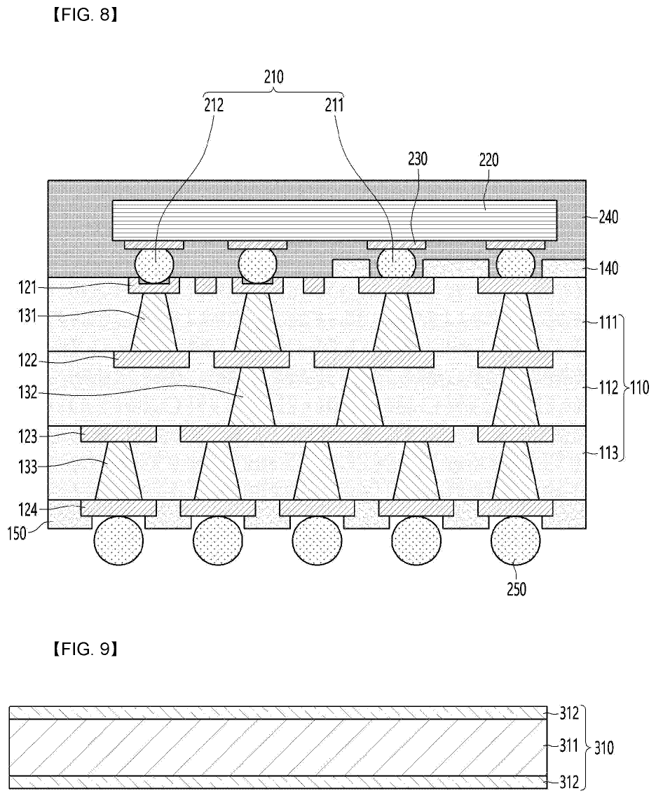

FIG. 8 is a view showing a semiconductor package according to an embodiment.

Referring to FIG. 8, the semiconductor package of the embodiment includes a circuit board shown in any one of FIGS. 2, 6, and 7, at least one chip mounted on the circuit board, a molding layer for molding the chip, and a connection part for combination with the chip or external board.

Hereinafter, a semiconductor package including the circuit board of FIG. 2 will be described. However, the embodiment is not limited to this, and a semiconductor package including the circuit board of FIG. 6 or FIG. 7 may be provided. Meanwhile, in the description of FIG. 7, it has been described that no recess is formed in the first pad 121-1, but as in FIG. 6, a recess may also be formed in the first pad 121-1 of FIG. 7.

For example, the semiconductor package 200 includes a connection part 210 disposed on the first circuit pattern layer 121 disposed on the outermost side of the circuit board. The connection part 210 may be disposed on the first pad 121-1 and the second pad 121-2 of the circuit board. For example, the connection part 210 may include a first connection part 211 disposed on the first pad 121-1 and a second connection part 212 disposed on the second pad 121-2.

The first connection part 211 and the second connection part 212 may have a hexahedral shape. For example, a cross section of the first connection part 211 and the second connection part 212 may have a rectangular shape. The cross section of the first connection part 211 and the second connection part 212 may include a rectangular or square shape. For example, the first connection part 211 and the second connection part 212 may have a spherical shape. For example, the cross section of the first connection part 211 and the second connection part 212 may include a circular shape or a semicircular shape. For example, the cross section of the first connection part 211 and the second connection part 212 may include a partially or entirely rounded shape. The cross sectional shape of the first connection part 211 and the second connection part 212 may be flat on one side and curved on the other side. The first connection part 211 and the second connection part 212 may be solder balls, but are not limited thereto.

Meanwhile, the embodiment may include a chip 220 disposed on the connection part 210. The chip 220 may be a processor chip. For example, the chip 220 may be an application processor (AP) chip selected from a central processor (e.g., CPU), a graphics processor (e.g., GPU), a digital signal processor, a cryptographic processor, a microprocessor, or a microcontroller. The terminal 230 of the chip 220 may be connected to the first pad 121-1 and the second pad 121-2 of the first circuit pattern layer 121 through the connection part 210.

In addition, although not shown in the drawing, the semiconductor package of the embodiment may further include an additional chip. For example, in an embodiment, at least two chips of a central processor (e.g., CPU), graphics processor (e.g., GPU), digital signal processor, encryption processor, microprocessor, and microcontroller may be disposed at regular intervals on the circuit board. For example, the chip 220 in the embodiment may include a central processor chip and a graphics processor chip, but is not limited thereto.

Meanwhile, the plurality of chips may be spaced apart from each other at a predetermined distance on the circuit board. For example, the spacing between the plurality of chips may be 150 μm or less. For example, the spacing between the plurality of chips may be 120 μm or less. For example, the spacing between the plurality of chips may be 100 μm or less.

Preferably, the spacing between the plurality of chips may range from 60 μm to 150 μm. Preferably, the spacing between the plurality of chips may range from 70 μm to 120 μm. Preferably, the spacing between the plurality of chips may range from 80 m to 110 μm. When the spacing between the plurality of chips is less than 60 μm, problems with operation reliability may occur due to mutual interference between the plurality of chips. When the spacing between the plurality of chips is greater than 150 μm, signal transmission loss may increase as the distance between the plurality of chips increases. When the spacing between the plurality of chips is greater than 150 μm, the volume of the semiconductor package 200 may increase.

The semiconductor package 200 may include a molding layer 240. The molding layer 240 may be disposed to cover the chip 220. For example, the molding layer 240 may be EMC (Epoxy Mold Compound) formed to protect the mounted chip 220, but is not limited thereto.

The molding layer 240 may include a first part disposed on the first protective layer 140 and a second part disposed on the first insulating layer 111.

At this time, the molding layer 240 may have a low dielectric constant to increase heat dissipation characteristics. For example, the dielectric constant (Dk) of the molding layer 240 may be 0.2 to 10. For example, the dielectric constant (Dk) of the molding layer 240 may be 0.5 to 8. For example, the dielectric constant (Dk) of the molding layer 240 may be 0.8 to 5. Accordingly, the embodiment allows the molding layer 250 to have a low dielectric constant, thereby improving heat dissipation characteristics for heat generated from the chip 220.

Meanwhile, the semiconductor package 200 may include a connection part 250 disposed on the lowermost side of the circuit board. The connection part 250 may be disposed on the lower surface of the fourth circuit pattern layer 124 exposed through the second protective layer 150.

### —Manufacturing Method—

Hereinafter, a method of manufacturing a circuit board according to an embodiment will be described. Specifically, the manufacturing method of the circuit board shown in FIG. 2 will be described below in process order. However, the circuit board shown in FIGS. 6 and 7 can be manufactured using the following manufacturing method.

FIGS. 9 to 24 are diagrams showing the manufacturing method of the circuit board shown in FIG. 2 in order of process.

Referring to FIG. 9, the embodiment may prepare basic materials for manufacturing a circuit board using the ETS method.

For example, the embodiment may prepare a carrier board 310 in which a carrier insulating layer 311 and a metal layer 312 are disposed on at least one surface of the carrier insulating layer 311. At this time, the metal layer 312 may be disposed on only one of the first and second surfaces of the carrier insulating layer 311, or alternatively, may be disposed on both sides. For example, the metal layer 312 is disposed only on one side of the carrier insulating layer 311, and accordingly, the ETS process for manufacturing a circuit board can be performed only on that one side. Alternatively, the metal layer 312 may be disposed on both sides of the carrier insulating layer 311, and accordingly, the ETS process for manufacturing a circuit board can be performed simultaneously on both sides of the carrier board 311. In this case, two circuit boards can be manufactured at once.

The metal layer 312 may be formed by electroless plating on the carrier insulating layer 311. Alternatively, the carrier insulating layer 311 and the metal layer 312 may be CCL (Copper Clad Laminate).

Next, referring to FIG. 10, in the embodiment, a first dry film 320 is formed on the metal layer 312. At this time, the first dry film 320 may be disposed to cover the entire metal layer 312. Next, the embodiment may expose and develop the formed first dry film 320.

Specifically, the embodiment may proceed with a process of exposing and developing the first dry film 320 to form an opening 321 exposing the surface of the metal layer 312.

The opening 321 may be formed on the surface of the metal layer 312 to correspond to a region where the first circuit pattern layer 121 will be formed.

At this time, the embodiment may proceed with a process of curing the first dry film 320 in which the opening 321 is formed through the exposure and development.

Curing of the first dry film 320 may include curing using ultraviolet rays and curing using infrared rays.

For example, in the embodiment, the first dry film 320 may be cured using ultraviolet rays in the range of 5 mV to 100 mV. Alternatively, the embodiment may perform infrared heat curing of the first dry film 320.

As described above, the embodiment can improve the adhesion between the metal layer 312 and the first dry film 320 by additionally proceeding with the process of curing the first dry film 320. Accordingly, the embodiment enables miniaturization of the first circuit pattern layer 121 formed in the opening 321 by improving the adhesion between the first dry film 320 and the metal layer 312. For example, the embodiment further proceeds with a process of curing the first dry film 320, and as a result, the line width W1 and the spacing W2 of the traces 121-3 of the first circuit pattern layer 121 can be reduced. Furthermore, the embodiment may further proceed with a process of curing the first dry film 320, and as a result, it is possible to make the spacing W2 smaller than the line width W1 of the trace 121-3 of the first circuit pattern layer 121.

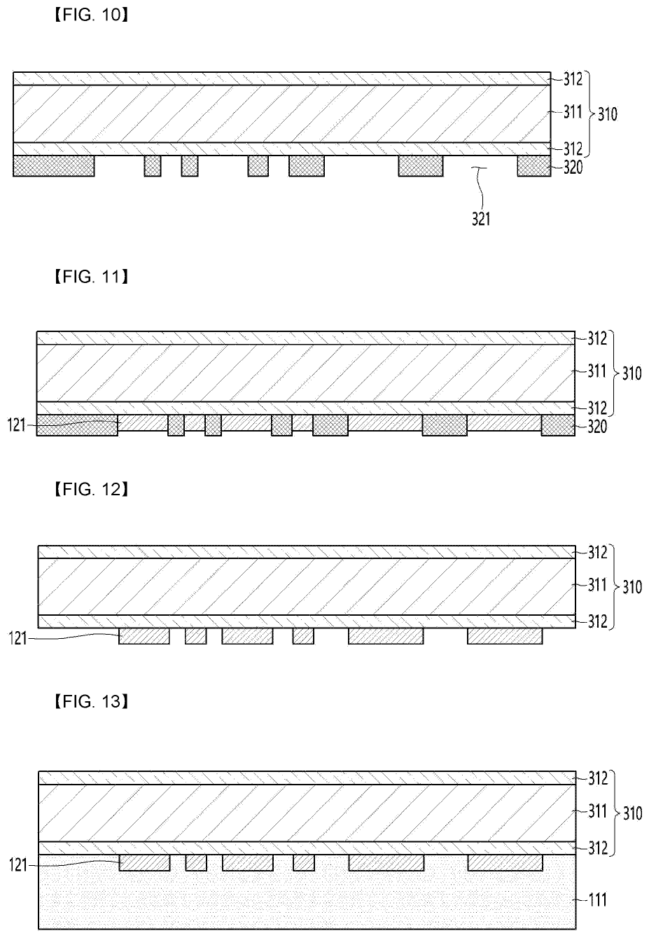

Next, referring to FIG. 11, in the embodiment may proceed with a process of forming the first circuit pattern layer 121 by using the metal layer 312 as a seed layer to form a plating layer in the opening 321 of the cured first dry film 320A.

Next, referring to FIG. 12, when the first circuit pattern layer 121A is formed, the embodiment may proceed with a process of removing the first dry film 320A may be performed.

Next, the embodiment may proceed with a process of pre-treating the first circuit pattern layer 121. For example, in the embodiment, the first circuit pattern layer 121 may be pretreated to provide a surface roughness of a certain level or more to the surface of the first circuit pattern layer 121. For example, in the embodiment, the first circuit pattern layer 121 is pretreated to form a first circuit pattern layer 121 having a 10-point average surface roughness (Rz) in the range between 0.01 μm and 0.5 μm.

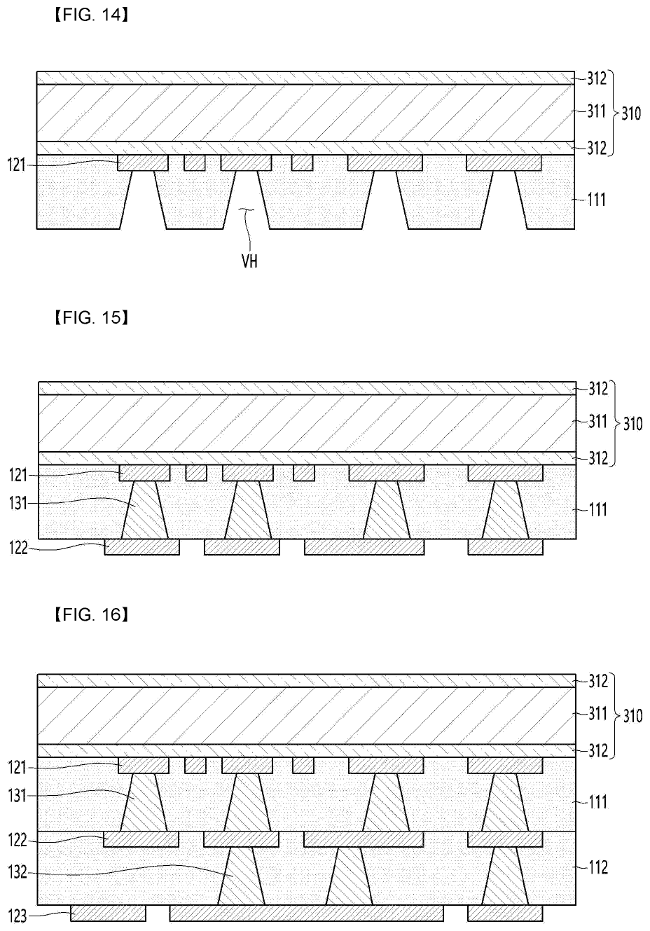

Next, in the embodiment, as shown in FIG. 13, a first insulating layer 111 covering the first circuit pattern layer 121 may be formed on the metal layer 312.

Next, referring to FIG. 14, the embodiment may proceed with a process of forming a via hole (VH) in the first insulating layer 111. The via hole (VH) may be formed by laser processing, but is not limited thereto.

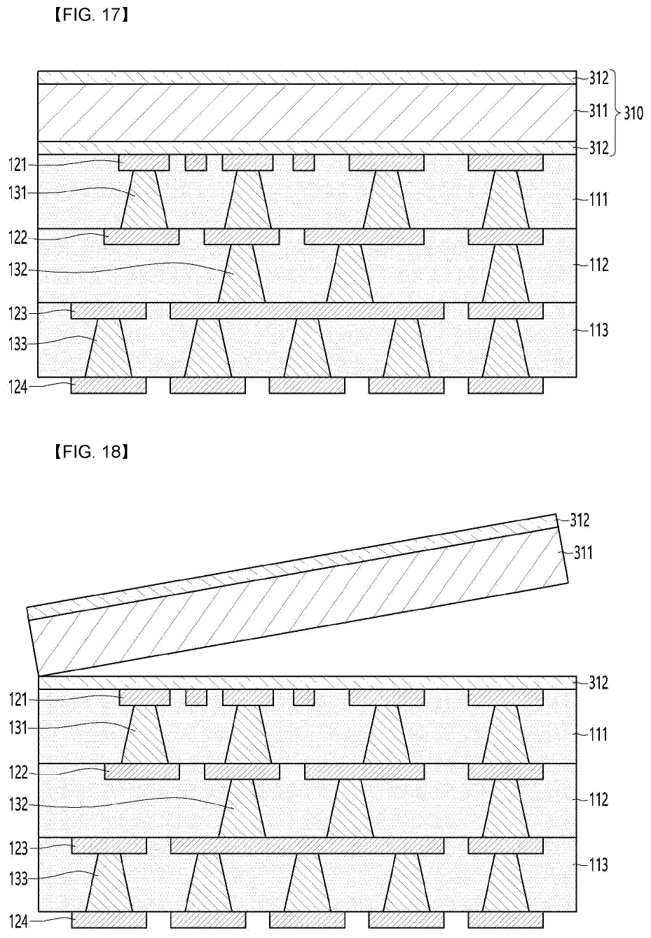

Next, referring to FIG. 15, the embodiment may proceed with a process of forming the first via 131 and the second circuit pattern layer 122.

Specifically, the embodiment may proceed with a process of forming a seed layer on the lower surface of the first insulating layer 111 and the inner wall of the via hole (VH) and a process of forming the second circuit pattern layer 122 and the first via 131 by performing electrolytic plating using the seed layer.

Next, in the embodiment, as shown in FIG. 16, a stacking process may be performed by repeating the processes shown in FIGS. 13 to 15.

Specifically, the embodiment may proceed with a process of forming a second insulating layer 112 covering the second circuit pattern layer 122 on the lower surface of the first insulating layer 111. Next, the embodiment may proceed with a process of forming a third via 133 penetrating the third insulating layer 113 and a fourth circuit pattern layer 124 protruding from the lower surface of the third insulating layer 113.

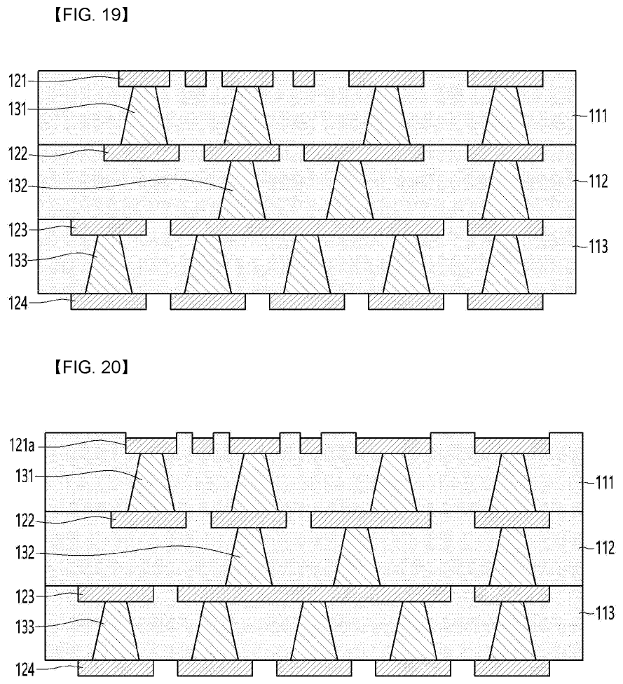

Next, as shown in FIG. 17, the embodiment may repeat the process shown in FIG. 16 to perform an additional lamination process.

Specifically, the embodiment may proceed with a process of forming a third insulating layer 113 covering the third circuit pattern layer 123 on the lower surface of the second insulating layer 112. Next, the embodiment may proceed with a process of forming a third via 133 penetrating the third insulating layer 113 and a fourth circuit pattern layer 124 protruding from the lower surface of the third insulating layer 113.

Next, as shown in FIG. 18, the embodiment may proceed with a process of removing the carrier board from the circuit board manufactured as above. For example, in the embodiment, a process may be performed to separate the carrier insulating layer 311 and the metal layer 312 from each other in the carrier board 310.

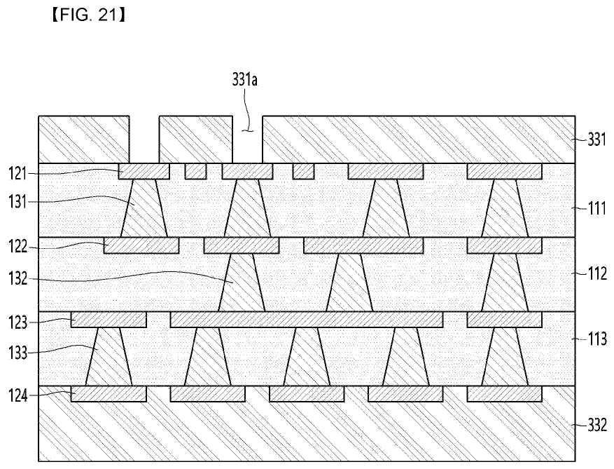

Next, as shown in FIG. 19, the embodiment may proceed with a process of etching and removing the metal layer 312 remaining on the upper surface of the first insulating layer 111 of the circuit board. Through this, in the embodiment, the upper surface of the first insulating layer 111 disposed on the uppermost side of the circuit board can be exposed.

At this time, the circuit board of FIG. 2 can be manufactured by changing the etching conditions of the metal layer 312, and the circuit board of FIG. 7 can be manufactured differently.

For example, only the metal layer 312 can be selectively removed depending on the etching conditions of the metal layer 312, and accordingly, the upper surface of the first circuit pattern layer 121 may be positioned on the same plane as the upper surface of the first insulating layer 111.

Alternatively, as shown in FIG. 20, a portion of the first circuit pattern layer 121a may be removed along with the metal layer 312, depending on the etching conditions of the metal layer 312, and a first circuit pattern layer 121a having a step difference from the first insulating layer 111 as shown in FIG. 7 may be formed.

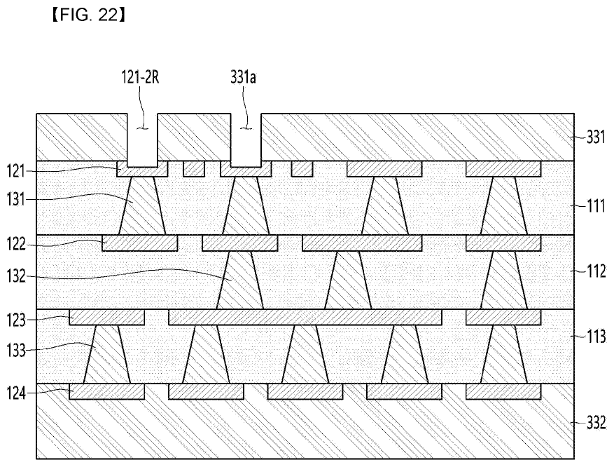

Next, as shown in FIG. 21, a first protective film 331 can be formed on the upper surface of the first insulating layer 111, and a second protective film 332 can be formed on the lower surface of the third insulating layer 113.

Thereafter, the embodiment may proceed with a process of forming an opening 331a in the first protective film 331. For example, the embodiment may form an opening 331a that exposes a portion of the upper surface of the second pad 121-2 disposed in the second region R2.

Next, as shown in FIG. 22, the embodiment may proceed with a process of forming a recess 121-2R by laser processing the upper surface of the second pad 121-2 exposed through the opening 331a.

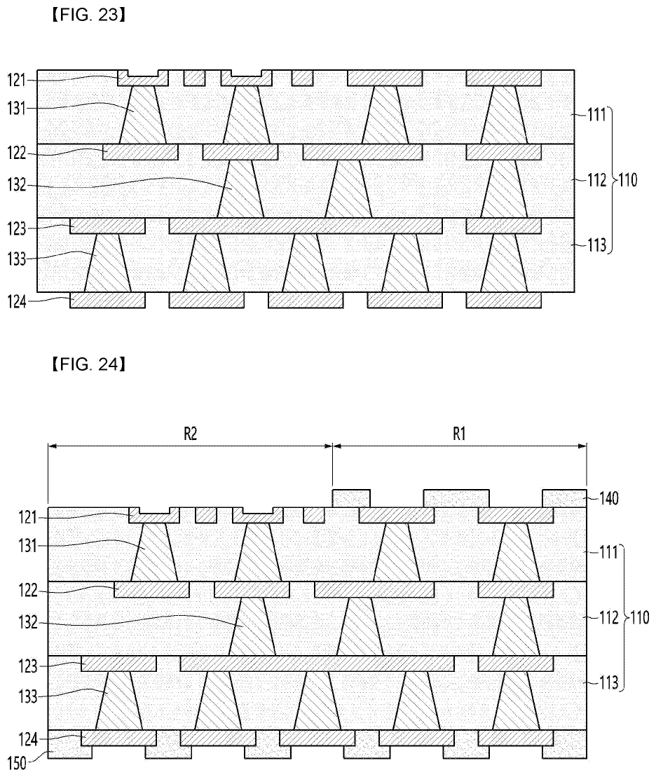

Next, as shown in FIG. 23, the embodiment may proceed with a process of removing the first protective film 331 and the second protective film 332.

Next, as shown in FIG. 24, the embodiment may form a first protective layer 140 having an opening in the first region R1 on the upper surface of the first insulating layer 111. In addition, the embodiment may proceed with a process of forming a second protective layer 150 having an opening on the lower surface of the third insulating layer 113.

The circuit board of the embodiment includes a first insulating layer disposed at a first outermost side and a first circuit pattern layer embedded in an upper surface of the first insulating layer. At this time, the first insulating layer includes a first region in which the first protective layer is disposed, and a second region other than the first region. In addition, the first circuit pattern layer includes a first pad disposed on the first region of the first insulating layer and a second pad disposed on the second region. In addition, a recess recessed in a downward direction may be formed on the upper surface of the second pad in the embodiment. In addition, the recess formed at the second pad may function as a dam to prevent overflow of connection parts such as solder balls disposed on the second pad. As described above, the embodiment allows a connection part to be stably formed on the second pad, thereby solving the reliability problem caused by overflow of the connection part. For example, the embodiment can solve an electrical reliability problem in which the connection part comes into contact with a neighboring circuit pattern layer as it overflows.

In addition, the embodiment may form a recess not only in the second pad but also in the first pad. That is, like the second pad, a connection part such as a solder ball is disposed on the first pad. At this time, if the recess is formed only on the second pad, a step may occur between the connection part disposed on the first pad and the connection part disposed on the second pad. In addition, the step may cause a problem in which the chip mounted on the connection part is tilted. Accordingly, the embodiment can eliminate the step by forming a recess in the first pad, and thus improve the mounting reliability of the chip.

In addition, the embodiment allows the upper surface of the first insulating layer and the upper surface of the first circuit pattern layer to have a step. For example, the embodiment allows the upper surface of the first circuit pattern layer to be positioned lower than the upper surface of the first insulating layer. Accordingly, the embodiment allows a part of the first insulating layer to serve as a dam to prevent overflow of the connection part, thereby further improving reliability. Furthermore, the embodiment can stably protect traces in the second region where the protective layer is not disposed, thereby improving product reliability.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other. Furthermore, when the circuit board having the above-described characteristics of the invention is used in a transportation device such as a vehicle, it is possible to transmit a high-current signal required by the vehicle at a high speed, thereby improving the safety of the transportation device. Furthermore, the circuit board and the semiconductor package including the same can be operated normally even in an unexpected situation occurring in various driving environments of the transportation device, thereby safely protecting the driver.

Features, structures, effects, etc. described in the above embodiments are included in at least one embodiment, and it is not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and variations should be interpreted as being included in the scope of the embodiments.

In the above, the embodiment has been mainly described, but this is only an example and does not limit the embodiment, and those of ordinary skill in the art to which the embodiment pertains will appreciate that various modifications and applications not illustrated above are possible without departing from the essential characteristics of the present embodiment. For example, each component specifically shown in the embodiment can be implemented by modification. And the differences related to these modifications and applications should be interpreted as being included in the scope of the embodiments set forth in the appended claims.

1.-10. (canceled)

11. A circuit board comprising:
an insulating layer; and
a circuit layer disposed on the insulating layer,
wherein the circuit layer includes a first pad having a first width along a horizontal direction, and a second pad having a second width along the horizontal direction,
wherein the second width is greater than the first width, and
wherein the first pad includes a recess provided on an upper surface thereof.

12. The circuit board of claim 11, wherein the circuit layer further includes a trace having a third width along the horizontal direction, and
wherein the first width is greater than the third width.

13. The circuit board of claim 12, wherein the first pad includes a 1-1 pad, and a 1-2 pad closest to the 1-1 pad along the horizontal direction,
wherein the second pad includes a 2-1 pad, and a 2-2 pad closest pad to the 2-1 pad along the horizontal direction, and
wherein a first distance between the 1-2 pad and the 1-2 pad along the horizontal direction is smaller than a second distance between the 2-1 pad and the 2-2 pad along the horizontal direction.

14. The circuit board of claim 13, wherein the trace is disposed between the 1-1 pad and the 1-2 pad.

15. The circuit board of claim 14, wherein the trace includes a plurality of trace lines, and
wherein at least one of the plurality of trace lines are connected to the first pad along the horizontal direction.

16. The circuit board of claim 11, wherein an upper surface of the first pad has a first shape, and an upper surface of the second pad has a second shape, and
wherein the first shape is different from the second shape.

17. The circuit board of claim 11, wherein the circuit layer is embedded in the insulating layer,
wherein a first stepped portion is provided between an upper surface of the first pad and an upper surface of the insulating layer, and
wherein a second stepped portion is provided between an upper surface of the second pad and the upper surface of the insulating layer.

18. The circuit board of claim 17, wherein a first depth of the first stepped portion is same with a second depth of the second stepped portion.

19. The circuit board of claim 17, wherein a first depth of the first stepped portion is different from a depth of the recess.

20. The circuit board of claim 11, further comprising:
a protective layer disposed on the insulating layer,
wherein the protective layer includes at least one opening.

21. The circuit board of claim 20, wherein the opening includes a first opening that overlaps the first pad in a vertical direction and a second opening that overlaps the second pad in a vertical direction, and
wherein a width of the first opening along the horizontal direction is different from a width of the second opening along the horizontal direction.

22. The circuit board of claim 21, wherein the width of the first opening along the horizontal direction is greater than the width of the second opening along the horizontal direction.

23. The circuit board of claim 22, wherein the width of the first opening along the horizontal direction is greater than the first width of the first pad, and
wherein the width of the second opening along the horizontal direction is smaller than the second width of the second pad.

24. The circuit board of claim 23, wherein the protective layer includes a first part in contact with an upper surface of the insulating layer and a second part in contact with an upper surface of the second pad, and
wherein a lower surface of the first part and a lower surface of the second part have a step.

25. The circuit board of claim 12, wherein a third stepped portion is provided between an upper surface of the trace and an upper surface of the insulating layer.

26. The circuit board of claim 11, wherein a width of the recess along the horizontal direction satisfies a range of 30% to 90% of the first width.

27. A semiconductor comprising:
an insulating layer;
a circuit layer disposed on the insulating layer; and
a semiconductor device disposed on the circuit layer,
wherein the circuit layer includes a first pad having a first width along a horizontal direction, and a second pad having a second width along the horizontal direction,
wherein the second width is greater than the first width, and
wherein the first pad includes a recess provided on an upper surface thereof.

28. The semiconductor of claim 27, further comprising:
a connection part disposed on the first pad,
wherein the connection part is disposed in the recess.

29. The semiconductor of claim 27, wherein the circuit layer further includes a trace having a third width along the horizontal direction,
wherein the first width is greater than the third width,
wherein the first pad includes a 1-1 pad, and a 1-2 pad closest to the 1-1 pad along the horizontal direction,
wherein the second pad includes a 2-1 pad, and a 2-2 pad closest pad to the 2-1 pad along the horizontal direction,
wherein a first distance between the 1-2 pad and the 1-2 pad along the horizontal direction is smaller than a second distance between the 2-1 pad and the 2-2 pad along the horizontal direction, and
wherein the trace is disposed between the 1-1 pad and the 1-2 pad.

30. The semiconductor of claim 29, wherein an upper surface of the first pad has a first shape, and an upper surface of the second pad has a second shape, and
wherein the first shape is different from the second shape.
